(19) United States
(12) Patent Application Publication
(10) Pub. No.: US 2010/0029019 A1
(43) Pub. Date: Feb. 4, 2010

(54) DETECTING MATERIALS ON WAFER AND REPAIR SYSTEM AND METHOD THEREOF

(75) Inventors: Heui Jae PARK, Seoul (KR); Heung Hyun SHIN, Seoul (KR); Il Hwan LEE, Seoul (KR)

Correspondence Address: VOLPE AND KOENIG, P.C., UNITED PLAZA, SUITE 1600, 30 SOUTH 17TH STREET, PHILADELPHIA, PA, 19103, US

(73) Assignee: SNU PRECISION CO. LTD., Seoul (KR)

(21) Appl. No.: 12/548,114

(22) Filed: Aug. 26, 2009

Related U.S. Application Data
(63) Continuation of application No. PCT/KR2008/002161, filed on Apr. 17, 2008.

(30) Foreign Application Priority Data
Apr. 25, 2007 (KR) 10-2007-0040355

(51) Int. Cl. H01L 21/66; G06K 9/00

(52) U.S. Cl. 438/4; 382/149; 257/E21.521

(57) ABSTRACT

Disclosed is a system and a method for detecting and repairing alien materials on a semiconductor wafer. The system includes a transfer arm for transferring and aligning a wafer, an inspection unit, on which the wafer is seated, and which obtains an image of the wafer surface, an analysis module for analyzing the alien material appearing in the image obtained by the inspection unit, and a repair unit for repairing the alien material according to information regarding the analyzed alien material. The simple construction of the system and method for detecting and repairing alien materials on a wafer reduces the manufacturing cost, avoids the loss of manufacturing cost, and increases the semiconductor chip yield ratio.

### CROSS REFERENCE TO RELATED APPLICATIONS

This application is a continuation of International Application No. PCT/KR2008/002161 filed Apr. 17, 2008, which claims priority to Korean Patent Application No. 10-2007-0040355, filed Apr. 25, 2007, which issued as Korean Patent No. 10-0863140 on Oct. 7, 2008, the entire contents of all of which are incorporated by reference as if fully set forth.

### FIELD OF INVENTION

The present invention relates to a system and a method for detecting and repairing alien materials on a semiconductor wafer. More particularly, the present invention relates to a system and a method for detecting alien materials on a semiconductor wafer and repairing the detected alien materials prior to or during an EDS process.

### BACKGROUND

In general, semiconductor manufacturing processes are divided into four processes, ranging from the initial wafer fabrication to completion of the product. Particularly, semiconductor manufacturing processes include a wafer fabrication process for fabricating a wafer from raw silicon, a wafer treatment process for forming a plurality of semiconductor chips on the wafer surface by using the fabricated wafer, an EDS (Electric Die Sorting) process for examining the electric characteristics of the semiconductor chips to determine whether they are acceptable or not, a package assembly process for fabricating chips from the treated wafer, and a module assembly process for attaching the package to a module to obtain a fully-functioning product.

During the semiconductor device manufacturing processes, wafers or chips formed on the wafers undergo frequent measurement and modification operations. In order to confirm whether or not corresponding wafers undergo measurement and modification processes as planned, optical microscopes, such as scanning electron microscopes or transmission electron microscopes, may be used. The EDS process refers to a process for examining the electric characteristics of semiconductor chips formed on a wafer to differentiate normally-functioning semiconductor chips from defective ones.

In the EDS process, a probe card is used to examine the electric characteristics of corresponding chips. Particularly, a specific level of current is applied to a plurality of semiconductor chips formed on a wafer to test the semiconductor chips and confirm whether they are normal or not.

Referring to FIG. 1, a semiconductor chip inspection device used in the EDS process includes an EDS tester 100 and a support table 130. The EDS tester 100 is adapted to apply electric signals to semiconductor chips on a wafer 140 to determine whether the inner-chip circuit is normal or not. The EDS tester 100 includes a probe card 110, a needle 120, a signal tester (not shown), and a support table 130. The needle 120 is spaced from the chip pad region of the wafer 140 by a very small distance d. The probe card 110 is connected to the needle 120 and the signal tester. Electric signals created by the signal tester are transmitted to the needle 120 via the probe card 110, and semiconductor chips formed on the wafer 140 receive the electric signals from the needle 120. Signals outputted by the chips in response to the electric signals are transmitted to the signal tester via the needle 120 and the probe card 110. The signal tester analyzes signals outputted by the semiconductor chips on the wafer 140 to determine whether the chips are normal or not.

The support table 130, on which a wafer due for the EDS process can be placed, includes an alignment device to improve the accuracy of inspection of chips on the wafer 140. Technical details regarding the EDS tester 100 are already disclosed in many publications, and additional description thereof will be omitted herein.

When the EDS tester 100 moves the needle 120 to inspect semiconductor chips formed on the wafer 140 aligned on the support table 130, the needle 120 may break due to an alien material A on the wafer 140, the height of which exceeds the allowable distance d between the needle 120 and the wafer 140. This may cause fatal defects and errors during the manufacturing processes. If the needle 120 is broken, the expensive manufacturing equipment must be replaced. In order to avoid such defects and errors, it is necessary to use inspection equipment for detecting the presence of alien materials and measuring their size, particularly their height, prior to the EDS process. In other words, the inspection equipment is used to detect alien materials of a predetermined height or larger, which may damage the equipment.

However, even after a polishing process, the wafer still has small protrusions B on its surface. That is, the surface of the wafer is not absolutely smooth, but only to an acceptable extent. Therefore, protrusions B may be erroneously detected as alien materials.

Meanwhile, the ratio of output (i.e. acceptable products) to the input after respective semiconductor manufacturing processes is defined as the yield ratio. For example, if the input is 100 and the output is 80, the yield ratio is 80. It is also possible to define the yield ratio for each process. The reason the yield ratio matters is that any mistake or problem occurring in the manufacturing processes fatally affects the products. Furthermore, considering that a number of semiconductor chips are obtained from a single wafer, if a semiconductor chip constituting a product is found defective, all semiconductor chips obtained from the same wafer must also be discarded. Therefore, the yield ratio of each process must be seriously considered. In summary, if the EDS process is conducted without detecting and repairing alien materials, the wafer may be damaged by the alien materials. This degrades the semiconductor chip yield ratio, and increases the manufacturing cost.

### SUMMARY

Therefore, the present invention has been made in view of the above-mentioned problems, and the present invention provides a system and a method for detecting and repairing alien materials on a wafer.

The present invention also provides a system for detecting and repairing alien materials on a wafer to reduce the manufacturing cost and improve the processes.

The present invention also provides a system and a method for detecting and repairing alien materials on a wafer to prevent the loss of manufacturing equipment.

The present invention also provides a system and a method for detecting and repairing alien materials on a wafer to increase the semiconductor chip yield ratio.

In accordance with an aspect of the present invention, there is provided a system for detecting and repairing an alien material on a semiconductor wafer, the system including a transfer arm for transferring a wafer; an inspection unit comprising a support table, the wafer being seated on the support table, a lateral light generator positioned on a side of the support table to emit light in a horizontal direction, a focusing lens positioned above the support table to receive light emitted by the lateral light generator and reflected by the alien material, and an imaging device positioned above the focusing lens to indicate the intensity of light received by the focusing lens; an analysis module for analyzing an image obtained by the imaging device and obtaining information regarding the alien material from the image; and a repair unit for receiving the information regarding the alien material analyzed by the analysis module and repairing the alien material.

The information regarding the alien material analyzed by the analysis module corresponds to position information and height information regarding the alien material.

Preferably, the analysis module includes a recognition module for recognizing the image obtained by the imaging device; a decoding module for reading the image recognized by the recognition module and creating the information regarding the alien material; a determination module for determining whether the alien material is to be repaired or not according to the information regarding the alien material read by the decoding module; and a transmission module for transmitting information regarding a target alien material to the repair unit, the target alien material being the alien material to be repaired.

The position information regarding the alien material read by the decoding module is an absolute coordinate calculated from an alignment point marked on the wafer.

Preferably, the repair module includes a reception module for receiving the information regarding the target alien material from the analysis module and a laser unit for repairing the target alien material.

According to another aspect of the present invention, there is provided a method for detecting and repairing an alien material on a semiconductor wafer, the method including the steps of transferring and aligning a semiconductor wafer; emitting light from a lateral surface of the aligned wafer to obtain a surface image of the wafer; recognizing and reading the surface image to create position information and height information regarding the alien material; comparing the information regarding the alien material with reference data to determine whether the alien material is to be repaired or not; transmitting information regarding a target alien material to a repair unit, the target alien material being the alien material to be repaired; and repairing the target alien material.

The system and method for detecting and repairing alien materials on a wafer according to the present invention are advantageous in that they can reduce the manufacturing cost and improve the processes.

Furthermore, the system and method for detecting and repairing alien materials on a wafer according to the present invention can prevent the loss of manufacturing equipment.

In addition, the system and method for detecting and repairing alien materials on a wafer according to the present invention can increase the semiconductor chip yield ratio.

### BRIEF DESCRIPTION OF THE DRAWINGS

The foregoing and other objects, features, and advantages of the present invention will become more apparent from the following detailed description when taken in conjunction with the accompanying drawings in which:

FIG. 1 is a sectional view of an inspection device used in an EDS process;

FIG. 2 briefly shows a system for detecting and repairing alien materials on a semiconductor wafer according to the present invention;

FIG. 3 is a sectional view showing the path of first light in connection with an inspection unit according to the present invention;

FIG. 4 is a sectional view showing the path of second light in connection with an inspection unit according to the present invention;

FIG. 5 is a flowchart of a method for detecting and repairing alien materials on a semiconductor wafer according to the present invention; and

FIG. 6 is a sectional view showing the path of light emitted by a lateral light generator according to the present invention.

DETAILED DESCRIPTION OF THE PREFERRED EMBODIMENTS

Hereinafter, exemplary embodiments of the present invention will be described with reference to the accompanying drawings.

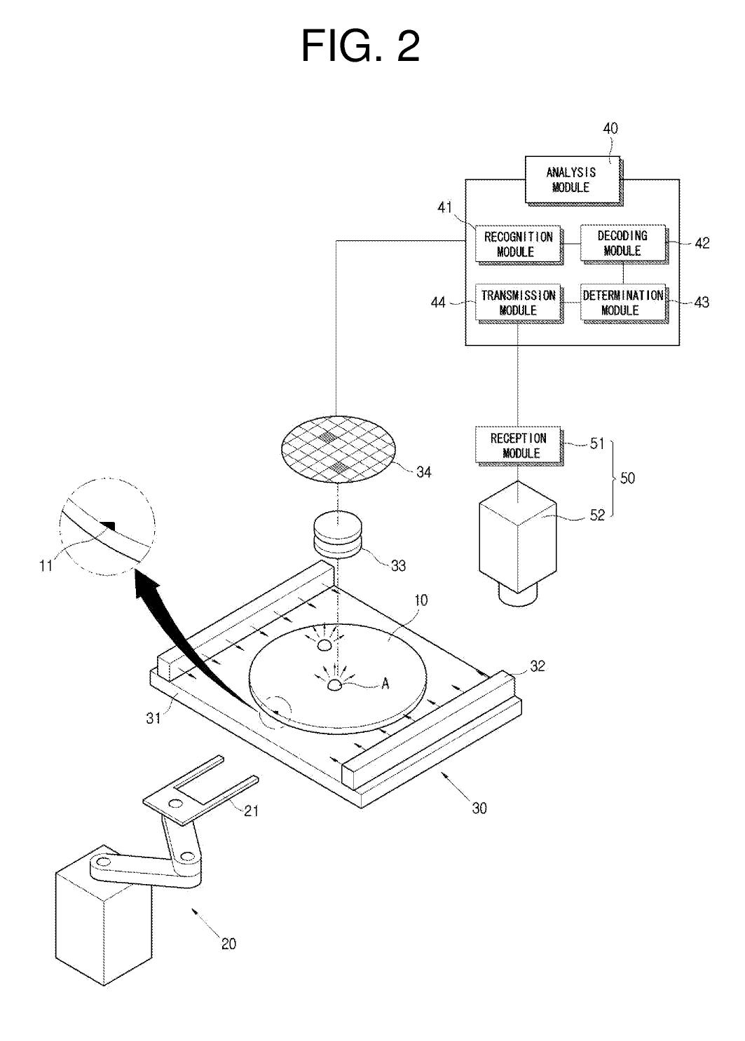

FIG. 2 briefly shows a system for detecting and repairing alien materials on a semiconductor wafer according to the present invention. Referring to FIG. 2, the system for detecting and repairing alien materials on a semiconductor wafer according to the present invention includes a transfer arm 20 for transferring a wafer 10, an inspection unit 30 for inspecting the wafer 10 transferred by the transfer arm 20, an analysis module 40 for analyzing the position of alien materials detected by the inspection unit 30, and a repair unit 50 for removing alien materials according to information regarding the position of the alien materials analyzed by the analysis module.

The wafer 10 has an alignment point 11 formed on one side so that, after the pre- treatment process, it can be aligned with and seated on the support table 31 of the inspection unit 30 (described later) by the transfer arm 20.

The transfer arm 20 consists of a robot arm, and has an arm portion 21 installed on an end to move the wafer 10 to the inspection unit 30.

The inspection unit 30 will now be described. The inspection unit 30 has a support table 31, on which the wafer 10 is aligned and seated, and lateral light generators 32 arranged on both sides of the support table 31 to emit light toward the wafer 10 in the horizontal direction.

The lateral light generators 32 are used to detect alien materials A on the wafer 10.

Particularly, light emitted by the lateral light generators 32 collide with alien materials A (e.g. pieces of glass) on the upper surface of the wafer 10 and undergo reflection or scattering. The optical axis of the lateral light generators 32 is preferably arranged in parallel with the upper surface of the wafer 10, which has the shape of a flat plate, so that the height of alien materials can be measured easily.

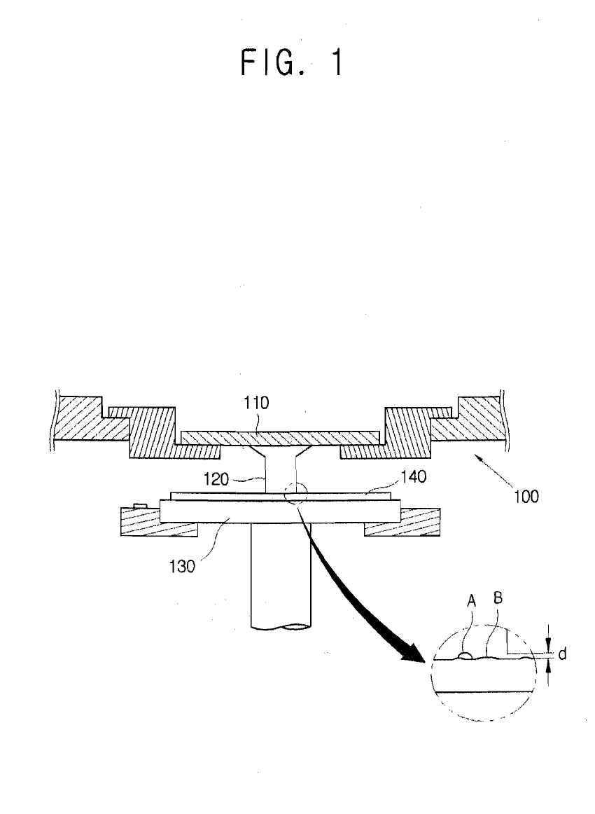

Focusing lenses 33 are arranged over the wafer 10 at a predetermined distance from it, and receive light emitted by the lateral light generators 32 and reflected by alien materials A or small surface protrusions B (FIG. 1). A number of focusing lenses 33 are arranged in respective regions over the wafer 10 so that light reflected by alien materials A or small surface protrusions are incident on the focusing lenses 33 in the corresponding overlying regions.

An imaging device 34 is arranged above the focusing lenses 33 to receive light emitted by the lateral light generators 32 and reflected by alien materials A or small surface protrusions. In other words, the imaging device 34 is positioned above the wafer 10 to obtain images of alien materials or small surface protrusions.

The imaging device may include CCDs (Charge Coupled Devices) or CMOSs (Complementary Metal Oxide Semiconductors).

The CCDs are expensive, but can obtain clear images with little noise. The CMOSs are less expensive than the CCDs, but have the problem of more noise. In general, the CCDs are about three times as bright as the CMOSs, and can obtain high-quality images accordingly. However, the CCDs consume more power than the CMOSs.

As a result of such construction, although light emitted by the lateral light generators 32 can travel through various paths, light propagating from the lateral light generators 32 are reflected by protrusions in the upward direction (i.e. in a direction perpendicular to the propagation direction), and are received by the focusing lenses 33 and the imaging device 34.

The above construction guarantees that the height of alien materials can be measured and calculated in proportion to the size of images (i.e. the number or area of pixels) obtained by the imaging device 34 (CCDs or CMOSs).

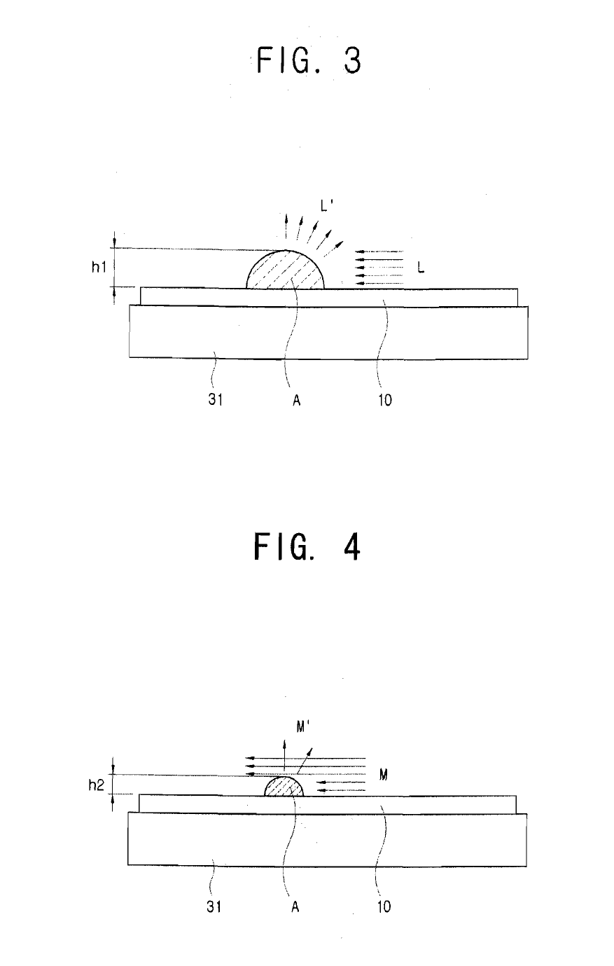

The principle of the inspection unit according to the present invention will now be described with reference to FIGS. 3 and 4.

FIG. 3 is a sectional view showing the path of first light in connection with an inspection unit according to the present invention. FIG. 4 is a sectional view showing the path of second light in connection with an inspection unit according to the present invention.

Referring to FIG. 3, the alien material A has a height of hi, and light L, particularly first light, propagates from the lateral light generators 32 until it is reflected by the alien material A. A portion of the light is reflected in a direction perpendicular to the propagation direction, and the upwardly reflected light L′ is received by the imaging device 34 (CCDs or CMOSs) via the focusing lenses 33.

The larger the height hi of the protrusion from the wafer 10 is, the more light L′ is reflected by the alien material A. As a result, the images obtained by the imaging device 34 (CCDs or CMOSs) become larger and brighter.

Referring to FIG. 4, the alien material A has a height of h2 (assumed to be smaller than hi), and light M, particularly second light, propagates from the lateral light generators 32 until it is reflected by the protrusion. A portion of the light is reflected in a direction perpendicular to the propagation direction, and the upwardly reflected light M′ is focused by the imaging device 34 via the focusing lenses 33.

Assuming with reference to FIGS. 3 and 4 that the height hi of the alien material A irradiated with first light (FIG. 3) is larger than the height h2 of the alien material A irradiated with second light (FIG. 4), a larger amount of light is reflected by the alien material A irradiated with the first light than in the case of the second light. Therefore, images obtained by the imaging device 34 (CCDs or CMOSs) are larger and brighter in the case of the first light.

In addition, assuming that the alien material A is semi-spherical, the height of the alien material A is proportional to the size (i.e. the number of pixels) and brightness of images obtained by the imaging device 34 (CCDs or CMOSs).

As such, the inspection unit 30 obtains images of the surface of the wafer 10 by using the lateral lighting devices, which emit light in parallel with the wafer 10, and the overlying focusing devices.

The analysis module 40 will now be described with reference to FIG. 2. The analysis module 40 plays the role of analyzing information (i.e. position, height) regarding small surface protrusions and alien materials, which appear in images obtained by the imaging device 34 of the inspection unit 30. The analysis module 40 includes a recognition module 41, a decoding module 42, a determination module 43, and a transmission module 44.

The recognition module 41 is adapted to recognize images obtained by the imaging device.

The decoding module 42 reads information regarding surface protrusions and alien materials that appear in the images recognized by the recognition module 41. The information regarding the surface protrusions and alien materials is related to their position and height. The position information corresponds to the absolute coordinate calculated from the alignment point 11 marked on the wafer.

The determination module 43 is adapted to determine whether an alien material is to be repaired or not according to information regarding the alien material read by the decoding module 42. The determination module 43 has been programmed to store reference data regarding heights and sizes so that the read information regarding the alien material, particularly the height information, is compared with the reference data to determine whether the alien material is to be repaired or not.

The transmission module 44 is adapted to transmit information regarding alien materials, which have been determined as repair targets by the determination module 42, to the repair unit 50 (described later).

The repair unit 50 will now be described. The repair unit 50 is adapted to receive information regarding alien materials, which are to be repaired, from the analysis module 40 and repair the alien materials. The repair unit 50 includes a reception module 51 and a laser unit 52.

The reception module 51 is adapted to receive information regarding alien materials from the transmission module 44 of the analysis module 40.

The laser unit 52 is adapted to emit lasers to corresponding alien materials according to information regarding the alien materials from the reception unit 51, particularly the position information (i.e. absolute coordinate), so that alien materials on the wafer are repaired.

Although it has been assumed in the present embodiment that the laser unit 52 is positioned on one side of the inspection unit and transferred by an additional transfer device so that lasers are emitted to corresponding alien materials, the laser unit 52 may also be positioned above the inspection unit 30 to emit lasers according to received information regarding alien materials.

A method for detecting and repairing alien materials on a semiconductor wafer by the above-mentioned system will now be described.

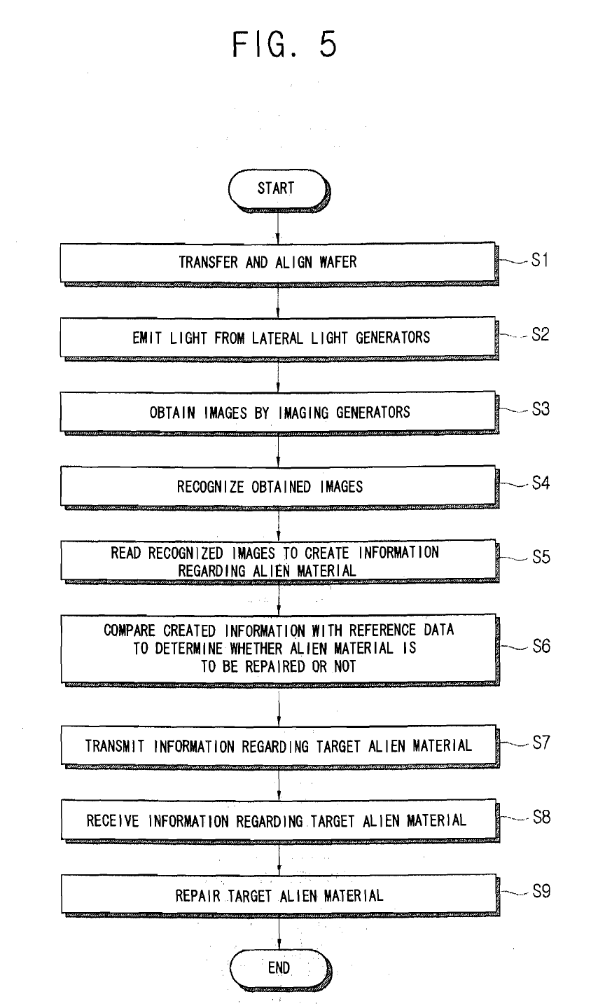

FIG. 5 is a flowchart of a method for detecting and repairing alien materials on a semiconductor wafer according to the present invention. Referring to FIG. 5, the wafer, which has undergone the pre-processes, is transferred by the transfer arm until it is aligned and seated on the support table of the inspection unit (S1).

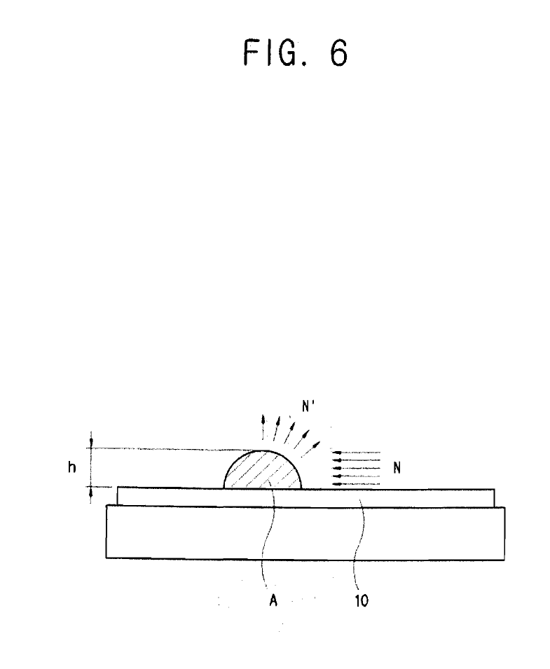

Referring to FIG. 6, the lateral light generators emit light N in parallel with the top of the aligned wafer 10 (S2). The emitted light propagates horizontally until it is reflected by an alien material A on the wafer 10 in a direction perpendicular to the direction of propagation, i.e. in the upward direction. The reflected light N′ is focused by the imaging device (CCDs or CMOSs) via the focusing lenses (S3).

The larger the height h of the alien material A from the wafer 10 is, the more light N′ is reflected by the alien material A. In addition, images obtained by the imaging device (CCDs or CMOSs) become brighter, and the number of pixels of the CCDs or CMOSs increases accordingly.

The images obtained by the imaging device are recognized by the recognition module of the analysis module (S4). The decoding module reads the recognized images to create information regarding surface protrusions or alien materials, particularly their position and height (S5). The reading module compares the created information with pre-stored reference data to determine whether the surface protrusions or alien materials are to be repaired or not (S6). The data to be compared is height information. If it is determined that an alien material is to be repaired, i.e. if information regarding the alien material has a value larger than the reference data, information regarding the corresponding alien material is transmitted via the transmission module (S7).

The reception module of the repair unit receives information regarding the alien material to be repaired (S8), and the laser unit repairs the corresponding alien material according to the received information (S8). Among the received information, information regarding the position (i.e. absolute coordinate) of the alien material is used. In other words, the laser unit repairs the alien material according to the absolute coordinate.

In this manner, alien materials on a semiconductor wafer are detected and repaired.

As mentioned above, the system and method for detecting and repairing alien materials on a semiconductor wafer according to the present invention are advantageous in that alien materials of a predetermined size or larger are detected and repaired by a lateral light device before EDS processes are conducted. This avoids the loss of manufacturing equipment and reduces the manufacturing cost. Furthermore, the processes are improved, and the semiconductor chip yield ratio is increased.

Although several exemplary embodiments of the present invention have been described for illustrative purposes, those skilled in the art will appreciate that various modifications, additions and substitutions are possible, without departing from the scope and spirit of the invention as disclosed in the accompanying claims.

The inventive system for detecting and repairing alien materials on a wafer reduces the manufacturing cost and improves the processes.

What is claimed is:

1. A system for detecting and repairing an alien material on a semiconductor wafer, the system comprising: a transfer arm for transferring a wafer; an inspection unit comprising a support table, the wafer being seated on the support table, a lateral light generator positioned on a side of the support table to emit light in a horizontal direction, a focusing lens positioned above the support table to receive light emitted by the lateral light generator and reflected by the alien material, and an imaging device positioned above the focusing lens to indicate the intensity of light received by the focusing lens; an analysis module for analyzing an image obtained by the imaging device and obtaining information regarding the alien material from the image; and a repair unit for receiving the information regarding the alien material analyzed by the analysis module and repairing the alien material.

2. The system as claimed in claim 1, wherein the information regarding the alien material analyzed by the analysis module corresponds to position information and height information regarding the alien material.

3. The system as claimed in claim 2, wherein the analysis module comprises: a recognition module for recognizing the image obtained by the imaging device; a decoding module for reading the image recognized by the recognition module and creating the information regarding the alien material; a determination module for determining whether the alien material is to be repaired or not according to the information regarding the alien material read by the decoding module; and a transmission module for transmitting information regarding a target alien material to the repair unit, the target alien material being the alien material to be repaired.

4. The system as claimed in claim 3, wherein the position information regarding the alien material read by the decoding module is an absolute coordinate calculated from an alignment point marked on the wafer.

5. The system as claimed in claim 4, wherein the repair module comprises a reception module for receiving the information regarding the target alien material from the analysis module and a laser unit for repairing the target alien material.

6. A method for detecting and repairing an alien material on a semiconductor wafer, the method comprising the steps of: transferring and aligning a semiconductor wafer; emitting light from a lateral surface of the aligned wafer to obtain a surface image of the wafer; recognizing and reading the surface image to create position information and height information regarding the alien material; comparing the information regarding the alien material with reference data to determine whether the alien material is to be repaired or not; transmitting information regarding a target alien material to a repair unit, the target alien material being the alien material to be repaired; and repairing the target alien material.
